(19) United States
(12) Patent Application Publication
(10) Pub. No.: US 2024/0177975 A1
(43) Pub. Date: May 30, 2024

(54) COOLING PLATE AND PLASMA PROCESSING CHAMBER INCLUDING THE SAME

(71) Applicant: SEMES CO., LTD., Cheonan-si (KR)

(72) Inventors: Yong Jun BAE, Seoul (KR); Seung Pyo LEE, Cheonan-si (KR); Dong Jun PARK, Osan-si (KR); Chang Eon PARK, Cheonan-si (KR); Su Won KIM, Pyeongtaek-si (KR); Dho Young KIM, Asan-si (KR)

(73) Assignee: SEMES CO., LTD., Cheonan-si (KR)

(21) Appl. No.: 18/372,954

(22) Filed: Sep. 26, 2023

(30) Foreign Application Priority Data
Nov. 24, 2022 (KR) 10-2022-0159517

(51) Int. Cl. H01J 37/32; F28F 3/12

(52) U.S. Cl. CPC H01J 37/32522; F28F 3/12; H01J 37/32091; H01J 37/3244; H01J 37/32513; H01J 2237/002

(57) ABSTRACT

A cooling plate and a plasma processing chamber are proposed. The cooling plate is configured to allow air to flow throughout the entire region of a window while reducing a region of covering the window. The cooling plate is configured to cool a window configured to seal a plasma processing space at an upper portion, and the cooling plate includes a body having a circular plate shape covering a part of a center region of the window, an inlet through which a gas is introduced into the body, and an outlet through which the gas is discharged from the body to the window. A flow path through which the gas flows and a slope formed from the flow path toward the window are formed between the inlet and the outlet.

### CROSS-REFERENCE TO RELATED APPLICATION

The present application claims priority to Korean Patent Application No. 10-2022-0159517, filed Nov. 24, 2022, the entire contents of which is incorporated herein for all purposes by this reference.

### BACKGROUND

### Field of the Invention

The present disclosure relates to a cooling plate and a plasma processing chamber including the same, the cooling plate being configured to cool a window that seals the plasma processing space at an upper portion.

### Description of the Related Art

A semiconductor manufacturing process is a process for manufacturing a semiconductor device on a substrate (e.g., a wafer), and includes, for example, exposure, deposition, etching, ion implantation, and cleaning. In order to perform each manufacturing process, semiconductor manufacturing equipment that performs each process is provided in a clean room of a semiconductor manufacturing plant, and each process is performed on a substrate put into the semiconductor manufacturing equipment.

A process using plasma, for example, etching, deposition, etc. is widely used in the semiconductor manufacturing processes. The process of plasma processing is performed by loading a substrate in a plasma processing space, and applying power by an antenna located at an upper portion while supplying a gas for plasma processing. A window for voltage application performed by the antenna while sealing the plasma processing space is provided at the upper portion. However, when the temperature of the window rises over a predetermined level by power applied by the antenna, a device is required to maintain the window at a constant temperature because a temperature change can affect plasma distribution and the substrate.

In the related art, a method of cooling the window by injecting air into a plate covering the entire region of the window is used, but distortion occurs in transmission of an electromagnetic wave signal due to the plate, and there is a limitation such as deterioration of energy transmission efficiency.

### SUMMARY

The present disclosure is intended to provide a cooling plate and a plasma processing chamber, the cooling plate being configured to allow air to flow throughout the entire region of a window while reducing a region of covering the window.

According to the present disclosure, there is provided a cooling plate configured to cool a window configured to seal a plasma processing space at an upper portion of the plasma processing space, the cooling plate including: a body having a circular plate shape covering a part of a center region of the window; an inlet through which a gas may be introduced into the body; and an outlet through which the gas may be discharged from the body to the window. A bottom surface of the body includes a first flat bottom surface at a first level, a second flat bottom surface at a second level lower than the first level, and a curved surface. The first flat bottom surface is disposed between the curved surface and the second flat bottom surface. The inlet is connected to a first portion of the curved surface. The outlet is connected to a second portion of the curved surface.

According to the present disclosure, the curved surface may be formed such that the gas may be induced to an upper surface of the window disposed below the bottom surface of the body by the Coanda effect while flowing along the curved surface from the inlet.

According to the present disclosure, the curved surface may be formed to reduce a sectional area of a flow of the gas flowing between the bottom surface of the body and the window disposed below the bottom surface of the body.

According to the present disclosure, the curved surface is a convex surface protruding toward the window.

According to the present disclosure, the inlet may be located at an upper surface of the body.

According to the present disclosure, the outlet may be located at an outer space of the body.

According to the present disclosure, the cooling plate includes a plurality of support parts disposed at an outer portion of the body. The outlet is provided in plural, and the plurality of outlets are spaced apart from each other, and each of the plurality of outlet is disposed between corresponding two adjacent support parts of the plurality of support parts.

According to the present disclosure, there is provided a cooling plate configured to cool a window configured to seal a plasma processing space at an upper portion of the plasma processing space, the cooling plate including: a body having a ring shape covering a part of an edge of the window; an inlet through which a gas may be introduced into the body; and an outlet through which the gas may be discharged from the body to the window. A bottom surface of the body includes a vertical wall surface, a flat bottom surface, and a curved surface, the flat bottom surface is disposed between the vertical wall surface and the curved surface, the inlet is connected to a portion of the flat bottom surface, and the outlet is connected to an end portion of the curved surface.

According to the present disclosure, there is provided plasma processing chamber including: a housing of which an upper portion may be open, the housing providing a plasma processing space; an upper module provided to cover the open upper portion of the housing; a support unit provided in the housing, and configured to support a substrate; and a shower head unit provided in the housing, and configured to supply a process gas for processing the substrate into the housing. The upper module may include: a window configured to seal the plasma processing space an upper portion; a cooling plate configured to cool the window; and an antenna member located at an upper portion of the cooling plate and configured to generating plasma into the plasma processing space. The cooling plate may include: an inner body having a circular plate shape covering a part of a center region of the window; an outer body having a ring shape covering a part of an edge of the window; a first inlet through which a gas may be introduced into the inner body and a second inlet through which a gas is introduced into the outer body; and a first outlet through which the gas may be discharged from the inner body and a second outlet through which the gas is discharged from the outer body to the window. A flow path through which the gas may flow and a slope formed from the flow path toward the window may be formed between the inlet and the outlet. A first bottom surface of the inner body includes a first flat bottom surface at a first level, a second flat bottom surface at a second level lower than the first level, and a first curved surface, the first flat bottom surface is disposed between the first curved surface and the second flat bottom surface, wherein the first inlet is connected to a first portion of the first curved surface, and the first outlet is connected to a second portion of the first curved surface. A bottom surface of the body includes a vertical wall surface, a flat bottom surface, and a curved surface, the flat bottom surface is disposed between the vertical wall surface and the curved surface, the second inlet is connected to a portion of the flat bottom surface, and the second outlet is connected to an end portion of the second curved surface.

According to the present disclosure, the slope is formed between the inlet and the outlet in the body covering a partial region of the window so that a gas flows on a surface of the window by the Coanda effect. Accordingly, while a region covering the window is reduced, air can flow throughout the entire region of the window.

### BRIEF DESCRIPTION OF THE DRAWINGS

FIG. 1 is a view showing a schematic structure of a plasma processing chamber according to the present disclosure.

FIG. 2 is a view showing an exterior shape of a cooling plate according to the present disclosure.

FIG. 3 is a view showing the Coanda effect.

FIGS. 4 and 5 are views showing an exterior shape of an inner cooling plate according to the present disclosure.

FIG. 6 is a view showing a section of the inner cooling plate according to the present disclosure.

FIG. 7 is a rear surface of the inner cooling plate according to the present disclosure.

FIGS. 8 and 9 are views showing an exterior shape of an outer cooling plate according to the present disclosure.

FIG. 10 is a view showing a section of the outer cooling plate according to the present disclosure.

FIG. 11 is a view showing a rear surface of the outer cooling plate according to the present disclosure.

FIG. 12 is a view showing a simulation result for a flow amount of a gas in the cooling plate according to the present disclosure.

### DETAILED DESCRIPTION

Hereinbelow, exemplary embodiments of the present disclosure will be described in detail with reference to the accompanying drawings such that the present disclosure can be easily embodied by one of ordinary skill in the art to which the present disclosure belongs. The present disclosure may be changed to various embodiments and the scope and spirit of the present disclosure are not limited to the embodiments described hereinbelow.

In the following description, if it is decided that the detailed description of known function or configuration related to the present disclosure makes the subject matter of the present disclosure unclear, the detailed description is omitted, and the same reference numerals will be used throughout the drawings to refer to the elements or parts with same or similar function or operation.

Furthermore, in various embodiments, an element with same configuration will be described in a representative embodiment by using the same reference numeral, and different configuration from the representative embodiment will be described in other embodiment.

Other words used to describe the relationship between elements should be interpreted in a like fashion such as “between” versus “directly between”, “adjacent” versus “directly adjacent”, etc. It will be further understood that the terms “comprises”, “comprising”, “includes”, and/or “including”, when used herein, specify the presence of stated features, integers, steps, operations, elements, and/or components, but do not preclude the presence or addition of one or more other features, integers, steps, operations, elements, components, and/or groups thereof.

Unless otherwise defined, all terms including technical and scientific terms used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

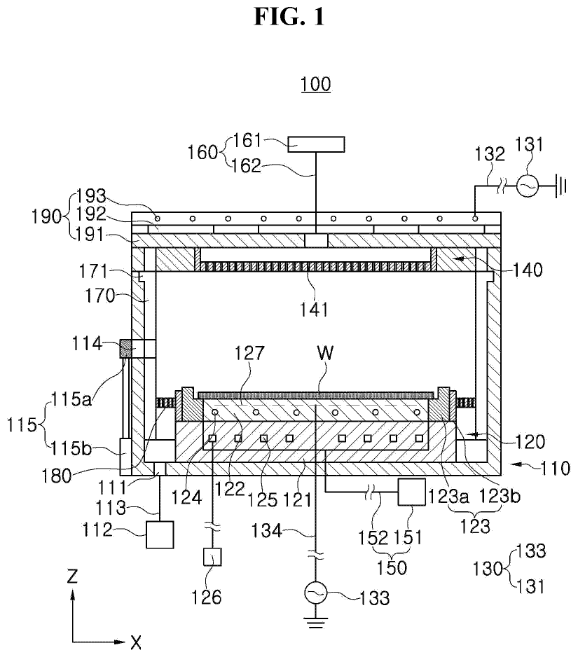

FIG. 1 is a view showing a schematic structure of a plasma processing chamber 100 according to the present disclosure. Referring to FIG. 1, the plasma processing chamber 100 may include a housing 110, a substrate the support unit 120, a plasma generation unit 130, a shower head unit 140, a first gas supply unit 150, a second gas supply unit 160, a wall liner unit 170, a baffle unit 180, and an upper module 190.

The plasma processing chamber 100 processes a substrate W (e.g., wafer) by using an etching process (e.g., dry etching process) in vacuum environment. The plasma processing chamber 100 may process the substrate W by using, for example, a plasma process.

The housing 110 provides a plasma processing space in which the plasma process is performed. The housing 110 may have an exhaust hole 111 at a lower portion thereof.

The exhaust hole 111 may be connected to an exhaust line 113 to which a pump 112 is mounted. The exhaust hole 111 may discharge reaction a reaction byproduct generated in the plasma process and a gas remaining in the housing 110 out of the housing 110 via the exhaust line 113. In this case, the inside space (plasma processing space) of the housing 110 may be decompressed to a predetermined pressure.

The housing 110 may have an opening 114 at a lateral wall. The opening 114 may serve as a passage through which the substrate W enters the inside space of the housing 110. The opening 114 may be configured to be opened and closed by a door assembly 115.

The door assembly 115 may include an outer door 115a and a door actuator 115b. The outer door 115a may be provided at an outer wall of the housing 110. The outer door 115a may move in a vertical direction (Z direction) by the door actuator 115b. The door actuator 115b may be operated using a motor, a hydraulic cylinder, a pneumatic cylinder, etc.

The substrate the support unit 120 may be provided at a lower region in the housing 110. The substrate the support unit 120 may support the substrate W by using an electrostatic force. However, the embodiment is not limited thereto. The substrate the support unit 120 may support the substrate W in various methods such as a mechanical clamping, vacuum, etc.

When the substrate the support unit 120 supports the substrate W by using the electrostatic force, the substrate the support unit 120 may include a chuck body 121 and an electrostatic chuck 122.

The chuck body 121 may support the electrostatic chuck 122 at a lower portion. The chuck body 121 may be made of, for example, aluminum component as a material, and may be provided as an aluminum base plate.

The electrostatic chuck 122 may support the substrate W loaded on an upper portion thereof by using the electrostatic force. The electrostatic chuck 122 may be made of a ceramic component as a material and may be provided as a ceramic plate or a ceramic puck, and may be coupled to the chuck body 121 to be fixed to the chuck body 121.

A bonding layer may be formed between the chuck body 121 and the electrostatic chuck 122 formed thereabove, and a protecting layer may be provided an outskirt thereof to protect the bonding layer.

The electrostatic chuck 122 may be provided to be movable in a vertical direction (Z direction) in the housing 110 by using a driving member (not shown). When the electrostatic chuck 122 is formed to be movable in the vertical direction, the electrostatic chuck 122 may locate the substrate W in a region where more uniform plasma distribution is generated. A lower electrode 127 may be provided inside the electrostatic chuck 122 and generate plasma in the processing space of the plasma processing chamber 100.

A ring assembly 123 may be provided to wrap an edge of the electrostatic chuck 122. The ring assembly 123 has a ring shape, and may be configured to support an edge region of the substrate W. The ring assembly 123 may include a focus ring 123a and an insulation ring 123b.

The focus ring 123a is formed inside the insulation ring 123b, and is provided to wrap the electrostatic chuck 122. The focus ring 123a may be made of a silicone material, may focus plasma to the substrate W.

The insulation ring 123b is formed outside the focus ring 123a, and is provided to wrap the focus ring 123a. The insulation ring 123b may be made of a quartz material.

Meanwhile, the ring assembly 123 may include an edge ring (not shown) formed in close contact with an edge of the focus ring 123a. The edge ring may be formed to prevent a side surface of the electrostatic chuck 122 from being damaged by plasma.

The first gas supply unit 150 supplies a first gas to remove foreign materials remaining on an upper portion of the ring assembly 123 or an edge portion of the electrostatic chuck 122. The first gas supply unit 150 may include a first gas supply source 151 and a first gas supply line 152.

The first gas supply source 151 may supply N2 gas as the first gas. However, the embodiment is not limited thereto. The first gas supply source 151 may supply other gases or cleaning agent.

The first gas supply line 152 may be provided between the electrostatic chuck 122 and the ring assembly 123. For example, the first gas supply line 152 may be formed to be connected to a portion between the electrostatic chuck 122 and the focus ring 123a.

Meanwhile, the first gas supply line 152 is provided inside the focus ring 123a, and may be formed to be bent so as to be connected to a portion between the electrostatic chuck 122 and the focus ring 123a.

A heating member 124 and a cooling member 125 are provided to allow the substrate W to be maintained at a process temperature when the etching process is in progress in the housing 110. Therefore, the heating member 124 may be provided as a heating line, and the cooling member 125 may be provided as a cooling line.

The heating member 124 and the cooling member 125 may be provided inside the electrostatic chuck 122 to maintain the process temperature of the substrate W. As an example, the heating member 124 may be provided inside the electrostatic chuck 122, and the cooling member 125 may be provided inside the chuck body 121.

Meanwhile, the cooling member 125 may be supplied with a refrigerant by using a chiller 126. The chiller 126 may be provided at the outside space of the housing 110.

The plasma generation unit 130 generates plasma from a gas remaining in an electric discharge space. At this point, the electric discharge space means a space located above the electrostatic chuck 122 in the inside space of the housing 110.

The plasma generation unit 130 may generate plasma to the electric discharge space in the housing 110 by using an inductively coupled plasma (ICP) source. In the above case, the plasma generation unit 130 may apply a voltage to generate plasma by using an antenna 193 provided in the upper module 190 and the lower electrode 127 of the electrostatic chuck 122.

However, the embodiment is not limited thereto. The plasma generation unit 130 may generate plasma to the electric discharge space in the housing 110 by using a capacitively coupled plasma (CCP) source.

The plasma generation unit 130 may include an upper power supply 131 and a lower power supply 133.

The upper power supply 131 applies power to the upper electrode, i.e., to the antenna 193. The upper power supply 131 may be provided to control a property of plasma. The upper power supply 131 may be provided to adjust, for example, ion bombardment energy.

In FIG. 1, the upper power supply 131 is shown as one upper power supply, but a plurality of upper power supplies may be provided in the embodiment. When the plurality of upper power supplies 131 is provided, the plasma processing chamber 100 may include a first matching network (not shown) electrically connected to the plurality of upper power supplies.

The first matching network may match powers having frequencies of different magnitudes input from the upper power supplies to apply the power to the antenna 193.

Meanwhile, a first impedance matching circuit (not shown) may be provided on a first transmission line 132 connecting the upper power supply 131 to the antenna 193 while having an objective of matching impedance.

The first impedance matching circuit may act as a lossless manual circuit to allow electric energy to be efficiently (i.e., maximally) transmit from the upper power supply 131 to the antenna 193.

The lower power supply 133 is provided to apply power to the lower electrode, i.e., to the electrostatic chuck 122. The lower power supply 133 may serve as a plasma source that generates plasma, or may serve to control a property of plasma together with the upper power supply 131.

In FIG. 1, the lower power supply 133 is shown as one lower power supply, but like the upper power supply 131, a plurality of lower power supplies may be provided in the embodiment. When the plurality of lower power supplies 133 is provided, the plasma processing chamber 100 may include a second matching network (not shown) electrically connected to the plurality of lower power supplies.

The second matching network may match powers having frequencies of different magnitudes input from the lower power supplies to apply the powers to the electrostatic chuck 122.

Meanwhile, a second impedance matching circuit (not shown) may be provided on a second transmission line 134 connecting the lower power supply 133 to the electrostatic chuck 122 while having an objective of matching impedance.

The second impedance matching circuit may act as a lossless manual circuit like the first impedance matching circuit to allow electric energy to be efficiently (i.e., maximally) transmitted from the lower power supply 133 to the electrostatic chuck 122.

The shower head unit 140 may be provided vertically inside the housing 110 to face the electrostatic chuck 122. The shower head unit 140 may include a plurality of gas feeding holes 141 to spray a gas into the housing 110, and may have a larger diameter than a diameter of the electrostatic chuck 122.

Meanwhile, the shower head unit 140 may be made of a silicone component as a material, and may be made of a metal component as a material.

The second gas supply unit 160 supplies a process gas (second gas) into the housing 110 via the shower head unit 140. The second gas supply unit 160 may include a first gas supply source 161 and a second gas supply source 162.

The first gas supply source 161 supplies etching gas used to process the substrate W, as the process gas. The first gas supply source 161 may supply a gas including fluorine component (e.g., gas such as SF6, CF4, etc.) as the etching gas.

The first gas supply source 161 may be a single gas supply source that supplies the etching gas to the shower head unit 140. However, the embodiment is not limited thereto. A plurality of first gas supply sources 161 may be provided to supply the process gas to the shower head unit 140.

The second gas supply source 162 connects the first gas supply source 161 and the shower head unit 140 to each other. The second gas supply source 162 may transmit the process gas, which is supplied via the first gas supply source 161, to the shower head unit 140, so that the etching gas may be introduced into the housing 110.

Meanwhile, when the shower head unit 140 may be divided into a center zone, a middle zone, an edge zone, etc., the second gas supply unit 160 may include a gas distributor (not shown) and a gas distribution line (not shown) so as to supply the process gas to each zone of the shower head unit 140.

The gas distributor distributes the process gas to each zone of the shower head unit 140, which is supplied from the first gas supply source 161. The gas distributor may be connected to the first gas supply source 161 via the second gas supply source 162.

The gas distribution line connects the gas distributor and each zone of the shower head unit 140 to each other. Accordingly, the gas distribution line may transmit the process gas, which is distributed by the gas distributor, to each zone of the shower head unit 140.

Meanwhile, the second gas supply unit 160 may include a third gas supply source (not shown) to supply a deposition gas.

The third gas supply source may supply the deposition gas to the shower head unit 140 to allow anisotropic etching while protecting a later surface of a pattern of the substrate W. The second gas supply source may supply a gas such as C4F8, C2F4, etc., as the deposition gas.

A wall liner unit 170 is provided to protect an inner lateral surface of the housing 110 from arc discharge generated during a process in which the process gas is exited, foreign materials generated during a process of substrate processing. The wall liner unit 170 may have a cylindrical shape with open upper and lower portions thereof inside the housing 110.

The wall liner unit 170 may be provided to be adjacent to the inner lateral wall of the housing 110. The wall liner unit 170 may include a support ring 171 at an upper portion thereof. The support ring 171 may be formed to protrude from the upper portion of the wall liner unit 170 in an outward direction (i.e., first direction 10), and may place on the housing 110 to support the wall liner unit 170.

The baffle unit 180 may serve to exhaust a process byproduct of plasma, unreacted gas, etc. The baffle unit 180 may be provided between the inner lateral wall of the housing 110 and the electrostatic chuck 122. The baffle unit 180 may have a ring shape, and may have a plurality of through holes that are perforated in a vertical direction (i.e., third direction 30). The baffle unit 180 may control a flow of the process gas in response to the number and shape of the through holes.

The upper module 190 is provided to cover the open upper portion of the housing 110. The upper module 190 may include a window 191, a cooling plate 192, and the antenna 193.

The window 191 may be formed to cover the upper portion of the housing 110 so as to seal the internal space of the housing 110. The window 191 may have a plate shape (e.g., circular plate), and may be made of an insulation material (e.g., alumina (Al2O3).

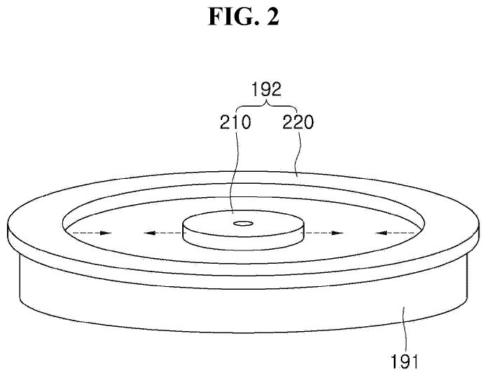

The window 191 may include a dielectric window, and the window 191 may have a through hole to allow the second gas supply source 162 to be inserted. When the plasma process is performed inside the housing 110, a coating layer may be formed on the window 191 to restrain generation of particle. The cooling plate 192 may move air to the window 191 to cool the window 191. A detailed structure of the cooling plate 192 will be described in detail with reference to FIGS. 2 to 10.

The antenna 193 may be installed above the window 191 and the cooling plate 192. The antenna 193 may have a cylindrical shape with an open lower portion, and may have a diameter corresponding to the housing 110. The antenna 193 may be provided to be attachable and detachable to the window 191.

The antenna 193 may serve as the upper electrode, and to which a coil provided to form a closed loop is mounted. The antenna 193 generates a magnetic field and an electric field inside the housing 110 on the basis of power supplied from the upper power supply 131, and serves to exit a gas introduced into the housing 110 via the shower head unit 140 into plasma.

The antenna 193 may be coiled with a coil having a planar spiral shape. However, the embodiment is not limited thereto. A structure or size of the coil may be variously changed by those skilled in the art.

Hereinbelow, the cooling plate 192 according to the present disclosure will be described. The cooling plate 192 may allow air to flow toward the window 191 to maintain the temperature of the window 191. The present disclosure provides the cooling plate 192 that reduces a region covering the window and allows the air to flow throughout the entire region of the window 191. According to the present disclosure, the cooling plate 192 may include an inner cooling plate 210 and an outer cooling plate 220.

Referring to FIG. 2, the inner cooling plate 210 is configured to cover a part of a center region of the window 191, and the outer cooling plate 220 is configured to cover a part of an edge region of the window 191. An empty space is provided between the inner cooling plate 210 and the outer cooling plate 220, so that an electromagnetic signal from the antenna 193 may be efficiently transmitted to the plasma processing space. The outer cooling plate 220 and the inner cooling plate 210 may be commonly referred to as the cooling plate. The cooling plate 192 may include only the outer cooling plate 220, and may include only the inner cooling plate 210, and may include both of the outer cooling plate 220 and the inner cooling plate 210.

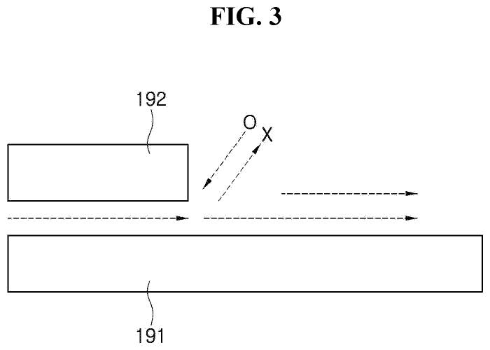

According to the present disclosure, the entire region of the window 191 is not covered but a partial region thereof is covered, so that the efficiency of transmission of the electromagnetic wave signal and cooling can be improved. However, in order to allow a gas to uniformly flow to the entire region of the window 191, the cooling plate 192 may be formed such that the gas flows to a surface of the window 191 by Coanda effect. The Coanda effect is an effect generated in a fluid flowing around a wall surface, and means a property of the fluid flowing on a solid surface to continue to flow along the solid surface. Referring to FIG. 3, since a gas flowing between the window 191 and the cooling plate 192 has a property of continuously flowing around the surface of the window 191, even when the cooling plate 192 is formed to cover the partial region of the window 191, the gas may flow along the surface of the window 191. Hereinbelow, the structure of the inner cooling plate 210 and the outer cooling plate 220, to which the Coanda effect is applied, will be described.

The inner cooling plate 210 includes a body 212 (inner body) having a circular plate shape that covers a partial region of the center portion of the window 191, an inlet 214 (first inlet) through which a gas is introduced into the body 212, and an outlet 216 (first outlet) through which a gas is discharged from the body 212 to the window 191. The body 212 has a bottom surface 212BS and an upper surface 222US. The bottom surface 212BS of the body 212 includes a first flat bottom surface 212BS-1 at a first level, a second flat bottom surface 212-BS-2 at a second level lower than the first level, and a curved surface 212BS-2 (or first curved surface). The first flat bottom surface 212BS-1 is disposed between the curved surface 212BS-3 and the second flat bottom surface 212BS-2. The inlet 214 is connected to a first portion 212BS-3a of the curved surface 212BS-3. The outlet 216 is connected to a second portion 212BS-3b of the curved surface 212BS-3.

A flow path 210A and a slope formed by the curve surface 212-BS-3 210B may be formed between the inlet 214 and the outlet 216, and the flow path 210A is provided for a gas to flow therethrough and the slope 210B is formed from the flow path 210A to the window 191. The flow path 210A is formed by an upper surface of the window 191 and the first flat bottom surface 212BS-1. The slope 210B is formed by the curve surface 212-BS-3.

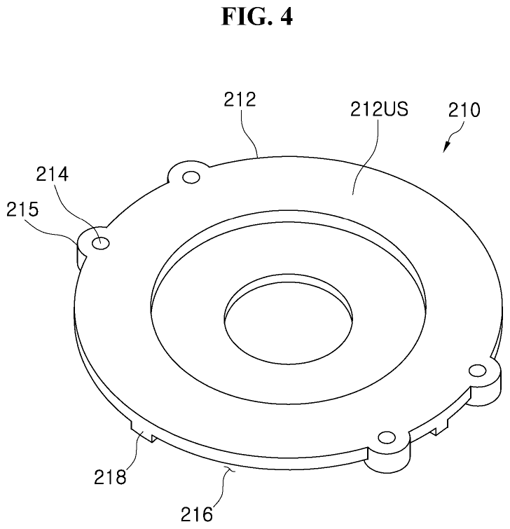

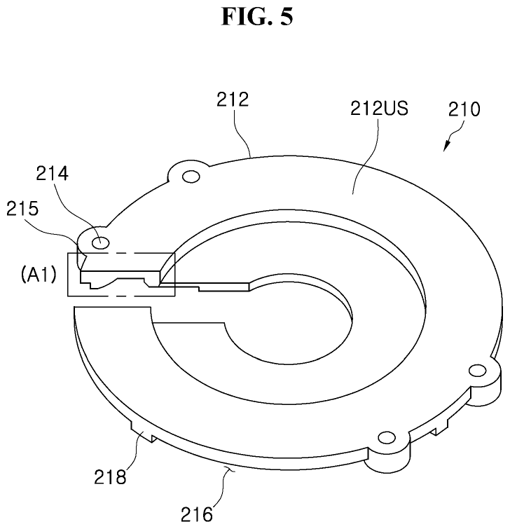

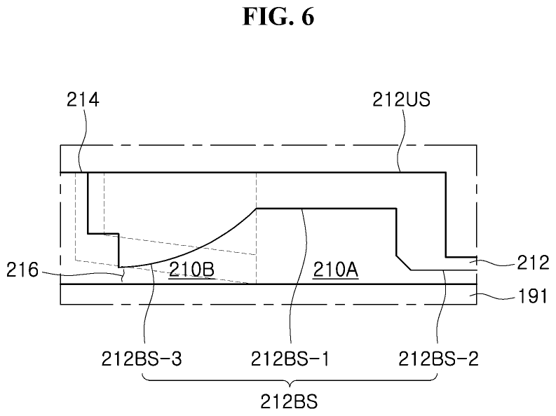

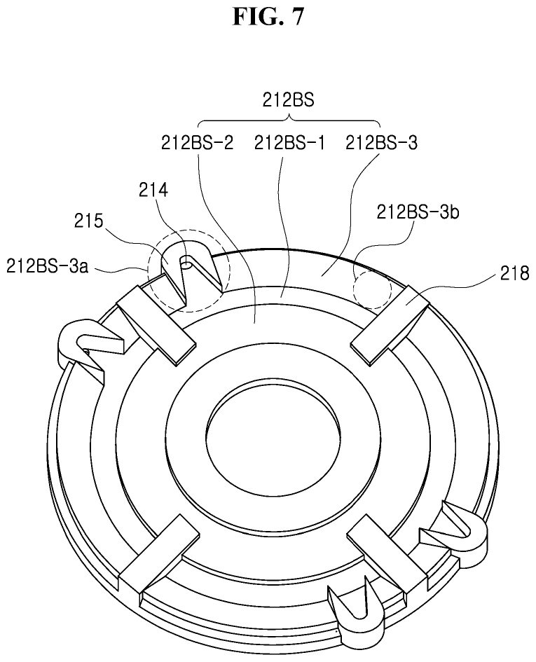

FIG. 4 is a view showing an exterior shape of the inner cooling plate 210. FIG. 5 is a view showing an inner structure of the inner cooling plate 210. FIG. 6 is an enlarged view showing a sectional part A1 of the inner cooling plate 210 in FIG. 5. FIG. 7 is a view showing a rear surface of the inner cooling plate 210.

Referring to FIGS. 4 and 5, the body 212 of the inner cooling plate 210 has a circular plate shape with an open center portion. The inlet 214 of the inner cooling plate 210 is located on an upper surface 212US of the body 212. As shown in FIGS. 4 and 7, the inlet 214 may be formed in a protrusion 215 protruding from the body 212. A gas supply tube (not shown) may be mounted to supply a gas to the inlet 214. The outlet 216 of the inner cooling plate 210 is located at the outer space of the body 212. The outlet 216 may be formed by a space between the body 212 and the window 191 and the gas may be discharged via the outlet 216.

The inner cooling plate 210 includes a plurality of support parts 218 disposed at an inner portion of the body 212. The outlet 216 is provided in plural. The plurality of outlets 216 are spaced apart from each other. Each of the plurality of outlets 216 is disposed between corresponding two adjacent support parts of the plurality of support parts 218.

The outlet 216 of the inner cooling plate 210 may include a plurality of outlets 216 formed by spaces between support parts 218 formed at outer portions of the body 212.

The curved surface 212BS-3 is formed such that the gas is induced to an upper surface of the window disposed below the bottom surface 212BS of the body 212 by the Coanda effect while flowing along the curved surface 212BS-3 from the inlet 214.

The curved surface 212BS-3 is formed to reduce a sectional area of a flow of the gas flowing between the bottom surface 212BS of the body 212 and the window 191 disposed below the bottom surface 212BS of the body 212.

The curved surface 212BS-3 is a convex surface protruding toward the window 191.

The inlet 214 and the outlet 216 may be connected to each other so that the gas to flows. As shown in FIG. 6, the flow path 210A and the slope 210B may be formed between the inlet 214 and the outlet 216, and the flow path 210A is provided for the gas to flow therethrough and the slope 210B is formed from the flow path 210A to the window 191. The flow path 210A may have a constant shape so that the gas may uniformly flow, and the gas flows from the flow path 210A along the slope 210B and then is discharged via the outlet 216. The slope 210B is formed such that the gas flows along the slope 210B and is induced to the upper surface of the window 191 by the Coanda effect. The slope 210B is formed to reduce a sectional area of the gas flowing between the window 191 and the body 212. The slope 210B may have a curve shape that protrude toward the window 191. In other words, the gas introduced via the inlet 214 uniformly flows along the flow path 210A, and is induced toward the surface of the window 191 along the slope 210B and then is discharged via the outlet 216, eventually. The gas discharged via the outlet 216 may flow along the upper surface of the window 191 by the Coanda effect. Therefore, even when the window 191 is not entirely covered, the gas may uniformly flow throughout the entire region of the window 191 to cool the window 191. A similar mechanism may be applied to the outer cooling plate 220.

The outer cooling plate 220 includes a body 222 (outer body) having a ring shape that covers a partial region of an edge portion of the window 191, an inlet 224 (second inlet) through which a gas is introduced into the body 222, and an outlet 226 (second outlet) through which a gas is discharged from the body 222 to the window 191. The body 222 includes an upper surface 222US and a bottom surface 222BS. A bottom surface 222BS of the body 222 includes a vertical wall surface 222BS-1, a flat bottom surface 222BS-2, and a curved surface 222BS-3 (or second curved surface). The flat bottom surface 222BS-2 is disposed between the vertical wall surface 222BS-1 and the curved surface 222BS-3. The inlet 224 is connected to a portion 222BS-2a of the flat bottom surface 222BS-2. The outlet 226 is connected to an end portion 222BS-3a of the curved surface 222BS-3. A flow path 220A and a slope 220B may be formed between the inlet 224 and the outlet 226, and the flow path 220A is provided for a gas to flow therethrough and the slope 220B is formed from the flow path 220A to the window 191. The flow path 220A is formed by an upper surface of the window 191 and the vertical wall surface 222BS-1, the flat bottom surface 222BS-2. The slope 220B is formed by the curve surface 222BS-3.

The curved surface 222BS-3 is formed such that the gas is induced to the upper surface of the window 191 disposed below the bottom surface 222BS of the body 222 by the Coanda effect while flowing along the curved surface 222BS-3 from the inlet 224.

The curved surface 222BS-3 is formed to reduce a sectional area of a flow of the gas flowing between the bottom surface 222BS of the body 222 and the window 191 disposed below the bottom surface 222BS of the body 222.

The curved surface 222BS-3 is a convex surface protruding toward the window 191.

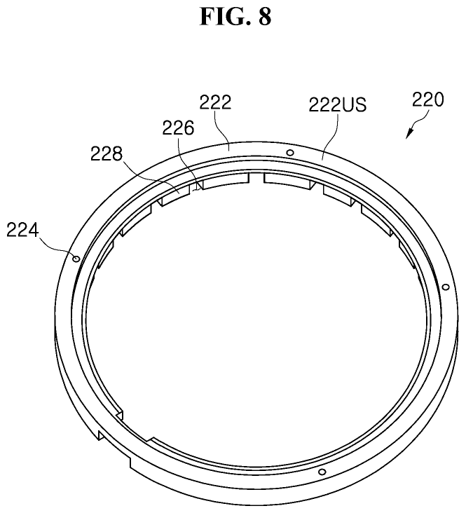

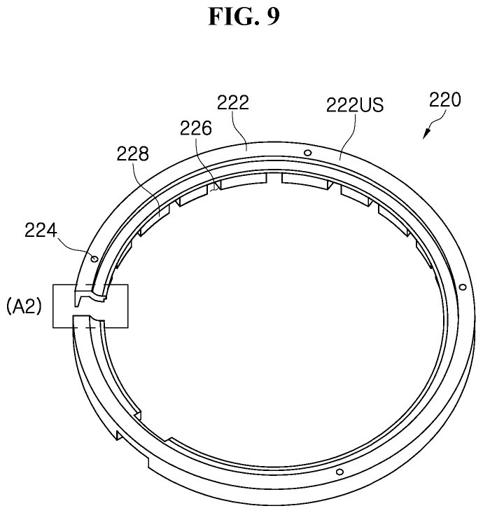

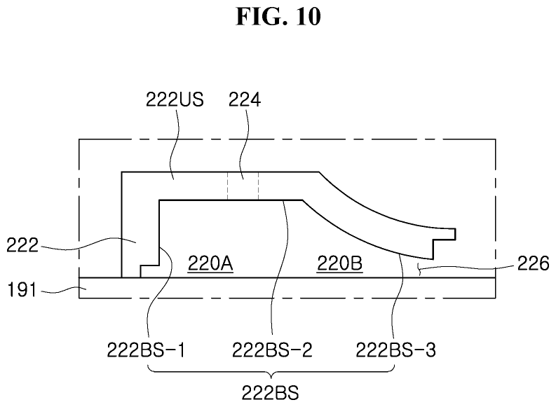

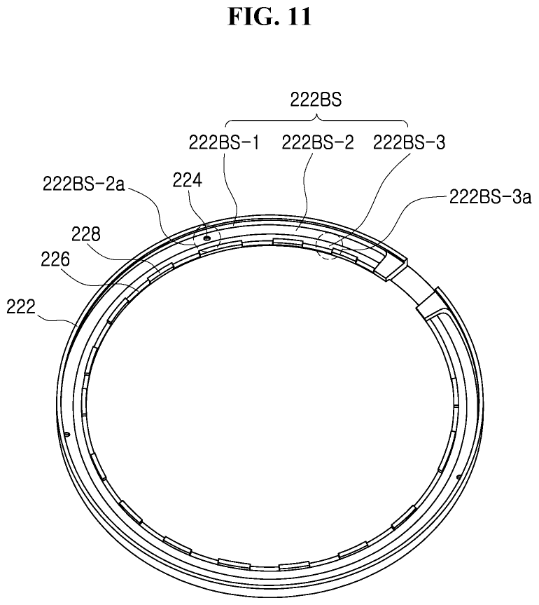

FIG. 8 is a view showing an exterior shape of the outer cooling plate 220. FIG. 9 is a view showing an inner structure of the outer cooling plate 220. FIG. 10 is an enlarged view showing a sectional part A2 of the outer cooling plate 220 in FIG. 9. FIG. 11 is a view showing a rear surface of the outer cooling plate 220.

Referring to FIGS. 8, 9, and 11, the body 222 of the outer cooling plate 220 has the ring shape corresponding to the edge portion of the window 191. The inlet 224 of the outer cooling plate 220 is located at a center portion of an upper surface 222US of the body 222. A gas supply tube (not shown) may be mounted to supply a gas to the inlet 224. The outlet 226 of the outer cooling plate 220 may be located at the inner space of the body 222. The outlet 226 may be formed by a space between the body 222 and the window 191 and the gas may be discharged via the outlet 226.

The outer cooling plate 220 includes a plurality of support parts 228 disposed at an inner portion of the body 222. The outlet 226 is provided in plural. The plurality of outlets 226 are spaced apart from each other. Each of the plurality of outlets 226 is disposed between corresponding two adjacent support parts of the plurality of support parts 228.

The outlet 226 of the outer cooling plate 220 may include a plurality of outlets 226 formed by spaces between support parts 228 formed at inner portions of the body 222.

The inlet 224 and the outlet 226 may be connected to each other so that the gas to flows. As shown in FIG. 10, the flow path 220A and the slope 220B may be formed between the inlet 224 and the outlet 226, and the flow path 220A is provided for the gas to flow therethrough and the slope 220B is formed from the flow path 220A to the window 191. The flow path 220A may have a constant shape so that the gas may uniformly flow, and the gas flows from the flow path 220A along the slope 220B and then is discharged via the outlet 226. The slope 220B is formed such that the gas flows along the slope 220B and is induced to the upper surface of the window 191 by the Coanda effect. The slope 220B is formed to reduce a sectional area of the gas flowing between the window 191 and the body 222. The slope 220B may have a curve shape that protrudes toward the window 191. In other words, the gas introduced via the inlet 224 uniformly flows along the flow path 220A, and is induced toward the surface of the window 191 along the slope 220B and then is discharged via the outlet 226, eventually. The gas discharged via the outlet 226 may flow along the upper surface of the window 191 by the Coanda effect. Therefore, even when the window 191 is not entirely covered, the gas may uniformly flow throughout the entire region of the window 191 to cool the window 191.

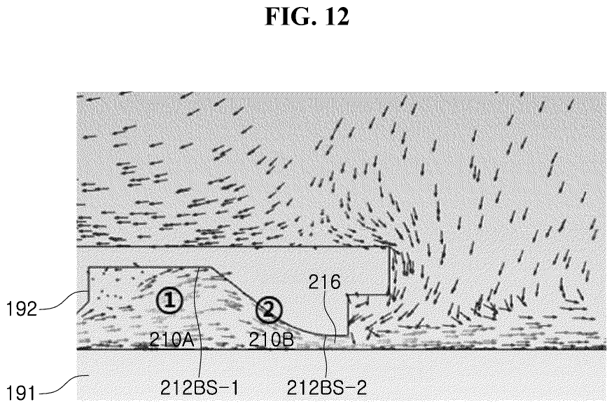

FIG. 12 is a view showing a simulation result for a flow amount of a gas in the cooling plate 192 according to the present disclosure. FIG. 10 shows an experimental result for a flow of air in the inner cooling plate 210, but it is obvious that a similar result may be derived from the outer cooling plate 220. As shown in FIG. 12, it is confirmed that the gas, which flows along the slope 210B in the flow path 210A of the cooling plate 192 and is discharged via the outlet 216, flows along the surface of the window 191 by Coanda effect. As described above, the cooling plate 192 has the shape that covers a partial region of the window 191 and the slope 210B is provided to generate the Coanda effect therein, so that it is possible to achieve uniform cooling performance of the window 191 while reducing loss or distortion of electromagnetic waves.

Although the preferred embodiments of the present disclosure have been disclosed for illustrative purposes, those skilled in the art will appreciate that various modifications, additions and substitutions are possible, without departing from the scope and spirit of the invention as disclosed in the accompanying claims. Since the present disclosure may be embodied in other specific forms without changing the technical sprit or essential features, those skilled in the art to which the present disclosure belongs should understand that the embodiments described above are exemplary and not intended to limit the present disclosure.

The scope of the present disclosure will be defined by the accompanying claims rather than by the detailed description, and those skilled in the art should understand that various modifications, additions and substitutions derived from the meaning and scope of the present disclosure and the equivalent concept thereof are included in the scope of the present disclosure.

What is claimed is:

1. A cooling plate configured to cool a window configured to seal a plasma processing space at an upper portion of the plasma processing space, the cooling plate comprising:
a body having a circular plate shape covering a part of a center region of the window;
an inlet through which a gas is introduced into the body; and
an outlet through which the gas is discharged from the body to the window,
wherein a bottom surface of the body includes a first flat bottom surface at a first level, a second flat bottom surface at a second level lower than the first level, and a curved surface,
wherein the first flat bottom surface is disposed between the curved surface and the second flat bottom surface,
wherein the inlet is connected to a first portion of the curved surface, and
wherein the outlet is connected to a second portion of the curved surface.

2. The cooling plate of claim 1, wherein the curved surface is formed such that the gas is induced to an upper surface of the window disposed below the bottom surface of the body by the Coanda effect while flowing along the curved surface from the inlet.

3. The cooling plate of claim 1, wherein the curved surface is formed to reduce a sectional area of a flow of the gas flowing between the bottom surface of the body and the window disposed below the bottom surface of the body.

4. The cooling plate of claim 1, wherein the curved surface is a convex surface protruding toward the window.

5. The cooling plate of claim 1, wherein the inlet is located at an upper surface of the body.

6. The cooling plate of claim 1, wherein the outlet is located at an outer space of the body.

7. The cooling plate of claim 6, further comprising:
a plurality of support parts disposed at an outer portion of the body,
wherein the outlet is provided in plural,
wherein the plurality of outlets are spaced apart from each other, and
wherein each of the plurality of outlets is disposed between corresponding two adjacent support parts of the plurality of support parts.

8. A cooling plate configured to cool a window configured to seal a plasma processing space at an upper portion of the plasma processing space, the cooling plate comprising:
a body having a ring shape covering a part of an edge of the window;
an inlet through which a gas is introduced into the body; and
an outlet through which the gas is discharged from the body to the window,
wherein a bottom surface of the body includes a vertical wall surface, a flat bottom surface, and a curved surface,
wherein the flat bottom surface is disposed between the vertical wall surface and the curved surface,
wherein the inlet is connected to a portion of the flat bottom surface, and
wherein the outlet is connected to an end portion of the curved surface.

9. The cooling plate of claim 8, wherein the curved surface is formed such that the gas is induced to an upper surface of the window disposed below the bottom surface of the body by the Coanda effect while flowing along the curved surface from the inlet.

10. The cooling plate of claim 8, wherein the curved surface is formed to reduce a sectional area of a flow of the gas flowing between the bottom surface of the body and the window disposed below the bottom surface of the body.

11. The cooling plate of claim 8, wherein the curved surface is a convex surface protruding toward the window.

12. The cooling plate of claim 8, wherein the inlet is located at an upper surface of the body.

13. The cooling plate of claim 8, wherein the outlet is located at an inner space of the body.

14. The cooling plate of claim 13, further comprising:
a plurality of support parts disposed at an inner portion of the body,
wherein the outlet is provided in plural,
wherein the plurality of outlets are spaced apart from each other, and
wherein each of the plurality of outlets is disposed between corresponding two adjacent support parts of the plurality of support parts.

15. A plasma processing chamber comprising:
a housing of which an upper portion is open, the housing providing a plasma processing space;
an upper module provided to cover the upper portion of the housing;
a support unit provided in the housing, and configured to support a substrate; and
a shower head unit provided in the housing, and configured to supply a process gas for processing the substrate into the housing,
wherein the upper module comprises:
a window configured to seal the plasma processing space and the upper portion;
a cooling plate configured to cool the window; and
an antenna member located at an upper portion of the cooling plate and configured to generate plasma in the plasma processing space,
wherein the cooling plate comprises an inner cooling plate and an outer cooling plate;
wherein the inner cooling plate comprises:
an inner body having a circular plate shape covering a part of a center region of the window;
a first inlet through which a gas is introduced into the inner body; and
a first outlet through which the gas is discharged from the inner body,
wherein a first bottom surface of the inner body includes a first flat bottom surface at a first level, a second flat bottom surface at a second level lower than the first level, and a first curved surface,
wherein the first flat bottom surface is disposed between the first curved surface and the second flat bottom surface,
wherein the first inlet is connected to a first portion of the first curved surface, and
wherein the first outlet is connected to a second portion of the first curved surface, and
wherein the outer cooling plate comprises:
an outer body having a ring shape covering a part of an edge of the window;
a second inlet through which a gas is introduced into the outer body; and
a second outlet through which the gas is discharged from the outer body to the window,
wherein a bottom surface of the outer body includes a vertical wall surface, a flat bottom surface, and a second curved surface,
wherein the flat bottom surface is disposed between the vertical wall surface and the second curved surface,
wherein the second inlet is connected to a portion of the flat bottom surface, and
wherein the second outlet is connected to an end portion of the second curved surface.

16. The plasma processing chamber of claim 15, wherein the first curved surface and the second curved surface are formed such that the gas is induced to an upper surface of the window disposed below the first bottom surface of the inner body and a second bottom surface by the Coanda effect while flowing along the first curved surface of the first inlet and the second curved surface of the second inlet.

17. The plasma processing chamber of claim 15, wherein the first curved surface and the second curved surface are formed to reduce a sectional area of a flow of the gas flowing between the window and the first and second flat bottom surfaces of the inner body, and wherein the window is disposed below the first and second flat bottom surfaces of the inner body.

18. The plasma processing chamber of claim 15, wherein each of the first curved surface and the second curved surface has a convex surface protruding toward the window.

19. The plasma processing chamber of claim 15, wherein the first inlet of the inner body is located at an upper surface of the inner body, and
an outlet of the inner body comprises a plurality of first outlets that are formed by spaces between support parts formed at an outer portion of the inner body.

20. The plasma processing chamber of claim 15, wherein the second inlet of the outer body is located at an upper surface of the outer body, and
an outlet of the outer body comprises a plurality of second outlets that are formed by spaces between support parts formed an inner portion of the outer body.
